(19) United States
(12) Patent Application Publication
(10) Pub. No.: US 2017/0293196 A1
(43) Pub. Date: Oct. 12, 2017

(54) DISPLAY DEVICE AND METHOD OF MANUFACTURING THE SAME

(71) Applicant: NEC Corporation, Tokyo (JP)

(72) Inventors: Chika MIYATAKE, Tokyo (JP); Kenichiro FUJII, Tokyo (JP)

(21) Appl. No.: 15/511,361

(22) PCT Filed: Sep. 11, 2015
(86) PCT No.: PCT/JP2015/075848

§ 371 Date: Mar. 15, 2017

(30) Foreign Application Priority Data
Sep. 19, 2014 (JP) 2014-191827

(51) Int. Cl. G02F 1/167; H01L 51/00; H01L 51/52; G02F 1/1333

(52) U.S. Cl. CPC G02F 1/167; G02F 1/133305; H01L 51/0097; H01L 51/5253; G02F 2201/50

(57) ABSTRACT

A display device includes a flexible display unit, an electronic component disposed on one surface thereof, and a coating layer that is elastically deformable to cover the electronic component, the coating layer has a fixed region fixed to one of the one surface of the flexible display unit and an end surface of an end portion, and a coating region configured to cover the electronic component is disposed inside the fixed region to be deformed to absorb distortion upon bending of the flexible display unit.

### TECHNICAL FIELD

The present invention relates to a display device having a flexible display unit and a method of manufacturing the same.

### BACKGROUND ART

In recent years, many display devices including flexible display units that are elastically deformable have been used. These display devices serving as flexible display units employ, for example, electronic papers or organic EL displays using an electrophoresis phenomenon as information display means or input means. These display devices are employed in various electronic instruments.

For example, a display device disclosed in Patent Literature 1 includes a housing formed of a material that is elastically deformable and having a connecting surface section that is foldable and a pair of base surface sections continuously formed at both of opposite sides of the connecting surface section with the connecting surface section sandwiched therebetween, and a flexible display having flexibility and attached to the housing in a thickness direction of the base surface sections, wherein a pair of base surface sections are to be opened and closed using the connecting surface section as a support portion.

### CITATION LIST

### Patent Literature

### [Patent Literature 1]

Japanese Unexamined Patent Application, First Publication No. 2013-174692

SUMMARY OF INVENTION

### Problem to be Solved by the Invention

However, in the display device disclosed in Patent Literature 1, since the flexible display having flexibility is fixed to the base surface sections of the housing while being adhered thereto, flexibility of the flexible display is inhibited due to fixation of the housing to the base surface sections, and bending properties of the flexible display cannot be sufficiently exhibited.

In consideration of the above-mentioned circumstances, the present invention is directed to provide a display device and a method of manufacturing the same that are capable of effectively protecting a flexible display unit constituted by a flexible display from excessive bending while maintaining flexibility of the flexible display unit.

### Means for Solving the Problem

A display device of the present invention has a flexible display unit; an electronic component installed on one surface of the flexible display unit; and a coating layer, which is deformable in part or as a whole, disposed on one surface of the flexible display unit to cover the electronic component, wherein the coating layer protects the flexible display unit as the coating layer is bent in part or as a whole according to deformation of the flexible display unit.

In addition, a method of manufacturing a display device of the present invention has a process of laminating an electronic component on one surface of a flexible display unit; and a process of stacking a coating layer, a portion or the entirety of which is deformable according to deformation of the flexible display unit, on one surface of the flexible display unit to cover the electronic component.

### Advantageous Effects of Invention

According to the present invention, the display device can be protected from excessive bending while maintaining flexibility of the flexible display unit.

### BRIEF DESCRIPTION OF DRAWINGS

FIG. 1 is a plan view showing a minimum configuration of a display device according to the present invention.

FIG. 2 is a cross-sectional view of a display device according to a first embodiment of the present invention.

FIG. 3A is a cross-sectional view showing a display device according to a second embodiment of the present invention.

FIG. 3B is a plan view showing the display device according to the second embodiment.

FIG. 4 is a perspective view showing a case in which the display device according to the second embodiment is bent.

FIG. 5A is a cross-sectional view showing a display device according to Variant 1 of the second embodiment.

FIG. 5B is a cross-sectional view showing a display device according to Variant 2 of the second embodiment.

FIG. 5C is a cross-sectional view showing a display device according to Variant 3 of the second embodiment.

FIG. 5D is a cross-sectional view showing a display device according to Variant 4 of the second embodiment.

FIG. 6A is a cross-sectional view showing a display device according to Variant 5 of the second embodiment.

FIG. 6B is a cross-sectional view showing a display device according to Variant 6 of the second embodiment.

FIG. 6C is a cross-sectional view showing a display device according to Variant 7 of the second embodiment.

FIG. 7A is a cross-sectional view showing a display device according to Variant 8 of the second embodiment.

FIG. 7B is a plan view showing the display device according to Variant 8 of the second embodiment.

FIG. 8A is a cross-sectional view showing a fixing means in a display device according to a third embodiment of the present invention.

FIG. 8B is a cross-sectional view showing another fixing means in the display device according to the third embodiment.

FIG. 9 is a cross-sectional view showing a display device according to a fourth embodiment of the present invention.

### EMBODIMENTS FOR CARRYING OUT THE INVENTION

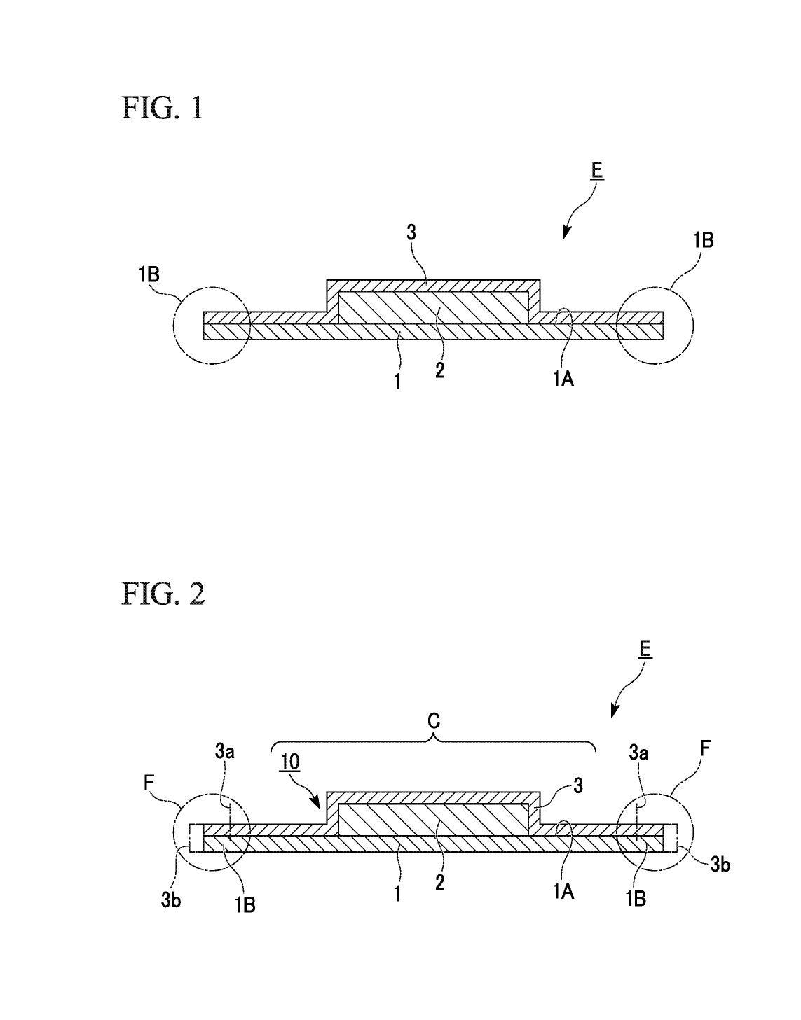

FIG. 1 is a view showing a minimum configuration of a display device E according to the present invention.

The display device E has a flexible display unit 1, an electronic component 2 stacked on one surface 1A of the flexible display unit, and a coating layer 3, which is deformable in part or as a whole, disposed on the one surface 1A of the flexible display unit 1 to cover the electronic component 2. The coating layer 3 protects the flexible display unit as the coating layer 3 is bent in part or as a whole according to deformation of the flexible display unit.

### First Embodiment

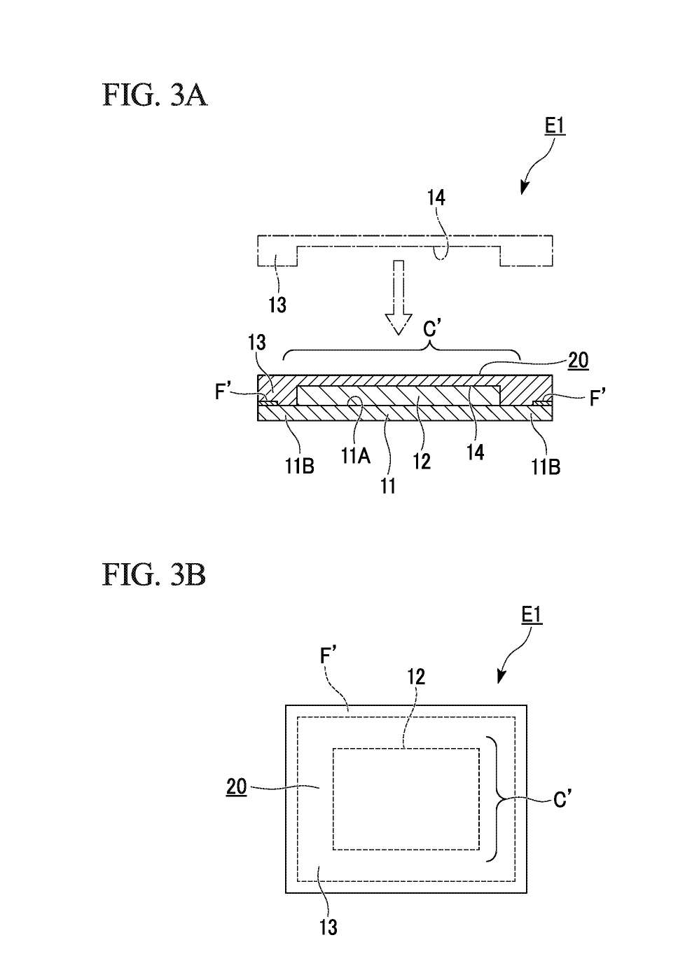

A first embodiment of the present invention will be described with reference to FIG. 2.

The display device E has the flexible display unit 1, the electronic component 2 laminated on a region of the flexible display unit 1, except for an end portion 1B of the one surface 1A, and formed of a material having stiffness higher than that of the flexible display unit 1, and the coating layer 3, which is elastically deformable, disposed on the one surface 1A of the flexible display unit 1 to cover the entire electronic component 2 as a housing.

The coating layer 3 has fixed regions F fixed to the flexible display unit 1, and a coating region C configured to cover the electronic component 2 is disposed inside the fixed regions F.

The coating layer 3 is fixed to at least one of end surfaces of the one surface 1A and the end portion 1B of the flexible display unit 1 in the fixed region F.

That is, when a length in a direction along a surface direction (a horizontal direction in the drawings) of the coating layer 3 is equal to that of the flexible display unit 1 or smaller than that of the flexible display unit 1 (for example, when the coating layer 3 has a length shown by reference numeral 3a), the coating layer 3 is fixed to the one surface 1A of the flexible display unit 1 in the fixed region F. In addition, when a length in the direction along the surface direction (the horizontal direction in the drawings) of the coating layer 3 is larger than that of the flexible display unit 1 (for example, when the coating layer 3 has a length shown by reference numeral 3b), the coating layer 3 is fixed to an end surface of the end portion 1B of the flexible display unit 1 in the fixed region F.

The inside of the fixed regions F in the coating layer 3 is a deformation section 10 configured to absorb distortion upon bending of the flexible display unit 1.

The deformation section 10 is installed at a place different from the fixed region F of the coating layer 3. The deformation section 10 absorbs distortion when the flexible display unit 1 is bent by an operation of a user through elastic deformation or expansion and contraction. In addition, when a force deforming the display device E as a whole is applied due to an impact such as dropping or the like, as the deformation section 10 is deformed, the flexible display unit 1 is protected. That is, in this case, the deformation section 10 is elastically deformed integrally with the flexible display unit 1 to bear a portion of stress generated in the flexible display unit 1. Alternatively, the deformation section 10 protects the flexible display unit 1 as the deformation section 10 is elastically deformed while sliding with respect to the flexible display unit 1 in the surface direction.

The coating layer 3 configured to cover the entire electronic component 2 on the flexible display unit 1 is formed on the display device E of the above-mentioned first embodiment, the coating layer 3 is fixed to at least one of the one surface 1A or the end portion 1B of the flexible display unit 1 in the fixed region F, and the deformation section 10 configured to absorb distortion upon bending of the flexible display unit 1 is formed inside the fixed regions F of the film layer 3.

That is, the deformation section 10 is formed in the coating layer 3 inside the fixed region F and at a place different from the fixed region F, distortion upon bending of the flexible display unit 1 being absorbed by the deformation section 10. The flexible display unit 1 can be effectively protected from an excessive bending operation of a user by absorption of distortion in the deformation section 10 while maintaining flexibility of the flexible display unit 1.

### Second Embodiment

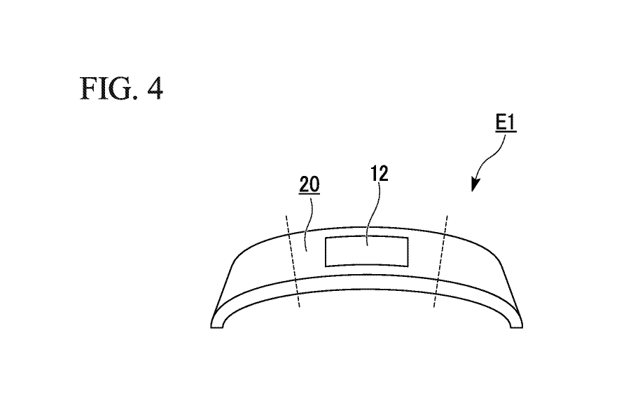

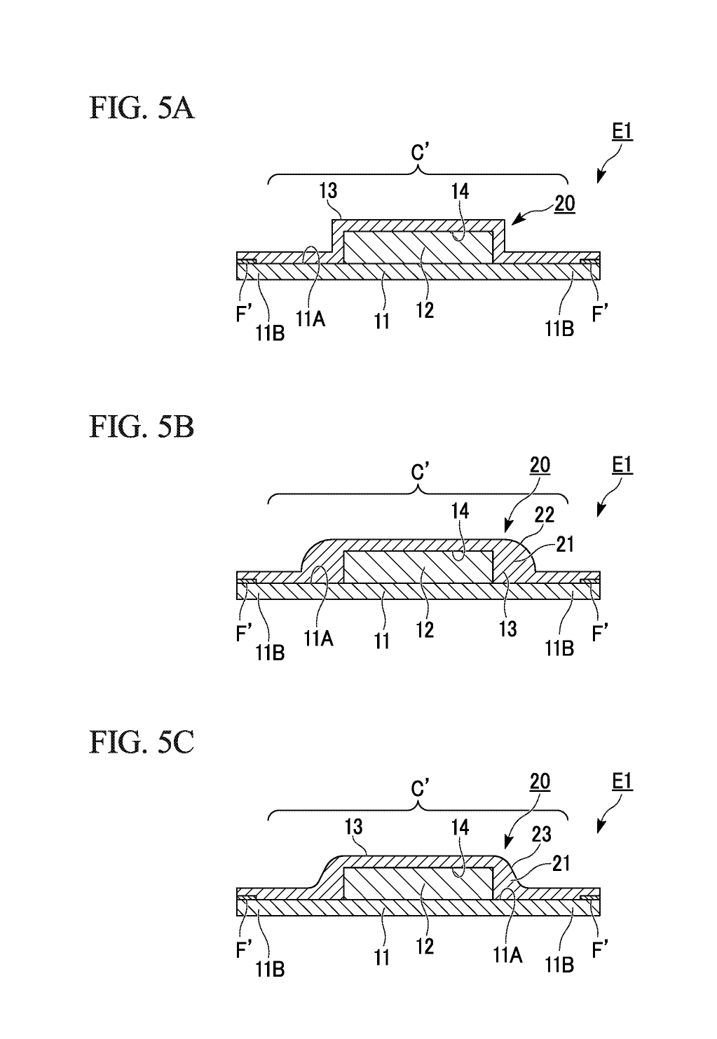

A display device E1 according to a second embodiment of the present invention will be described with reference to FIGS. 3A, 3B and 4.

FIGS. 3A and 3B show the display device E1 according to the second embodiment. The display device E1 has a flexible display unit 11 having a display screen at a lower side of the drawings, an electronic component 12 stacked on the flexible display unit 11 and formed of a material having stiffness higher than that of the flexible display unit 11, and a coating layer 13, which is elastically deformable, disposed on the flexible display unit 11 to cover the electronic component 12 as a whole. The electronic component 12 is constituted by materials having stiffness higher than that of the flexible display unit 11, for example, a packaged electronic device, a circuit board serving as a rigid printed circuit board on which an electronic component is mounted and connected by a conductor pattern, a connector including an electrical contact, a battery, and so on.

The electronic component 12 has a screen control unit and a power control unit that are configured to control a display screen of the flexible display unit 11. In addition, the electronic component 12 is disposed on a region on one surface 11A serving as a back surface of the flexible display unit 11, except for an end portion 11B of the surface 11A.

The coating layer 13 is disposed on the one surface 11A of the flexible display unit 11 to cover the electronic component 12 as a whole. As shown in FIG. 3B, the coating layer 13 has a fixed region F′ formed along the end portion 11B of the flexible display unit 11 and fixed to the flexible display unit 11. A coating region C′ configured to cover the electronic component 12 is disposed inside the fixed region F′.

The fixed region F′ of the coating layer 13 is fixed to at least one of the one surface 11A and the end portion 11B of the flexible display unit 11 by an adhesive force of the coating layer 13 itself constituted by an adhesive agent or a synthetic resin. In the coating layer 13, the coating region C′, except for the fixed region F′, is a non-fixed region in which an inner surface of the coating layer 13 is not fixed to the flexible display unit 11 or the electronic component 12.

When the fixed region F′ of the coating layer 13 is fixed to the one surface 11A of the flexible display unit 11, a length in a direction along a surface (a horizontal direction in the drawings) of the coating layer 13 is equal to or smaller than that of the flexible display unit 11. In addition, when the fixed region F′ of the coating layer 13 is fixed to the end portion 11B of the flexible display unit 11, a length in the direction along the surface (the horizontal direction in the drawings) of the coating layer 13 is larger than that of the flexible display unit 11.

As shown in FIG. 3A, a circuit receiving section 14 having a concave shape and having a cross section discontinuously bent to dispose the electronic component 12 is formed in an inner surface of the coating region C′ of the coating layer 13. In the display device E1 shown in the embodiment, the coating layer 13 is printed by covering the flexible display unit 11 on which the electronic component 12 is mounted with the coating layer 13 in a molten state and solidifying it. Alternatively, the coating layer 13 may be formed by fitting the circuit receiving section 14, previously given a concave shape, onto the electronic component 12.

A deformation section 20 is formed in the coating region C′ of the coating layer 13. The deformation section 20 is formed in the coating region C′ disposed inside the fixed region F′, and has a function of absorbing distortion upon bending of the flexible display unit 11 through deformation. The deformation section 20 is formed while being adhered and fixed to the electronic component 12 in the coating region C′ of the inner surface of the coating layer 13, i.e., while being relatively movable (or sliding) in the surface direction. As shown in FIG. 4, when the display device E1 is curved, as the deformation section 20 is deformed without varying a radius of curvature, distortion upon bending is absorbed.

In the deformation section 20, the coating layer 13 disposed on the circuit receiving section 14 having a concave shape has a thickness smaller than that of other portions. Even though the above-mentioned shape is provided, bending properties when the deformation section 20 is deformed can be improved.

In the display device E1 shown in the above-mentioned second embodiment, the fixed region F′ fixed to at least one of the one surface 11A and the end portion 11B of the flexible display unit 11 is formed in the coating layer 13 configured to cover the electronic component 12 on the flexible display unit 11 as a whole, and the deformation section 20 configured to absorb distortion upon bending of the flexible display unit 11 is formed in the coating region C′ inside the fixed region F′.

In the deformation section 20, since the coating region C′ of the inner surface of the coating layer 13 is not adhered and fixed to the electronic component 12, i.e., is formed while being relatively movable (or sliding) in the surface direction, as the deformation section 20 is freely deformed, distortion when the flexible display unit 11 is bent by a user is absorbed.

That is, in the coating layer 13 of the display device E1, the deformation section 20 is formed inside the fixed region F′ and at a place different from the fixed region F′, and distortion upon bending of the flexible display unit 11 is absorbed by the deformation section 20. The flexible display unit 11 can be effectively protected from an excessive bending operation of a user by absorption of distortion of the deformation section 20 while maintaining flexibility of the flexible display unit 11.

The deformation section 20 shown in the embodiment may be configured as described below.

### (Variant 1)

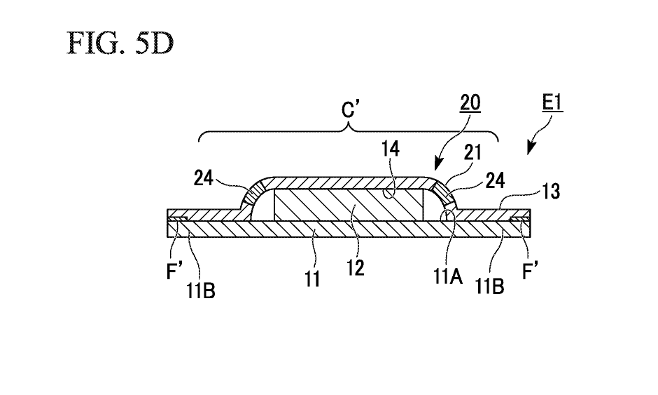

In the display device E1 shown in FIG. 3A, while a thickness of the coating layer 13 disposed on the circuit receiving section 14 having a concave shape is formed smaller than that of the other portion, the coating layer 13 may have a uniform thickness as a whole as shown in FIG. 5A. Accordingly, bending properties of the coating layer 13 as a whole can be improved.

### (Variant 2)

As shown in FIG. 5B, in the deformation section 20, a bent section 21 configured to absorb distortion upon bending of the flexible display unit 11 is further formed at the surroundings to cover the electronic component 12.

The bent section 21 shown in the example has a cross section formed in a fan shape 22, and distortion absorption performance of the deformation section 20 can be further improved by elastic deformation. of the bent section 21.

### (Variant 3)

As shown in FIG. 5C, the bent section 21 formed in the deformation section 20 has a cross section having an inclined surface 23, and distortion absorption performance of the deformation section 20 may be further improved by elastic deformation of the bent section 21.

### (Variant 4)

As shown in FIG. 5D, the bent section 21 formed in the deformation section 20 may be constituted by a region formed of an elastic material 24 serving as a portion of the coating layer 13 and being more flexible than the other portion. Distortion absorption performance of the deformation section 20 can be further improved by expansion and contraction deformation of the bent section 21.

### (Variant 5)

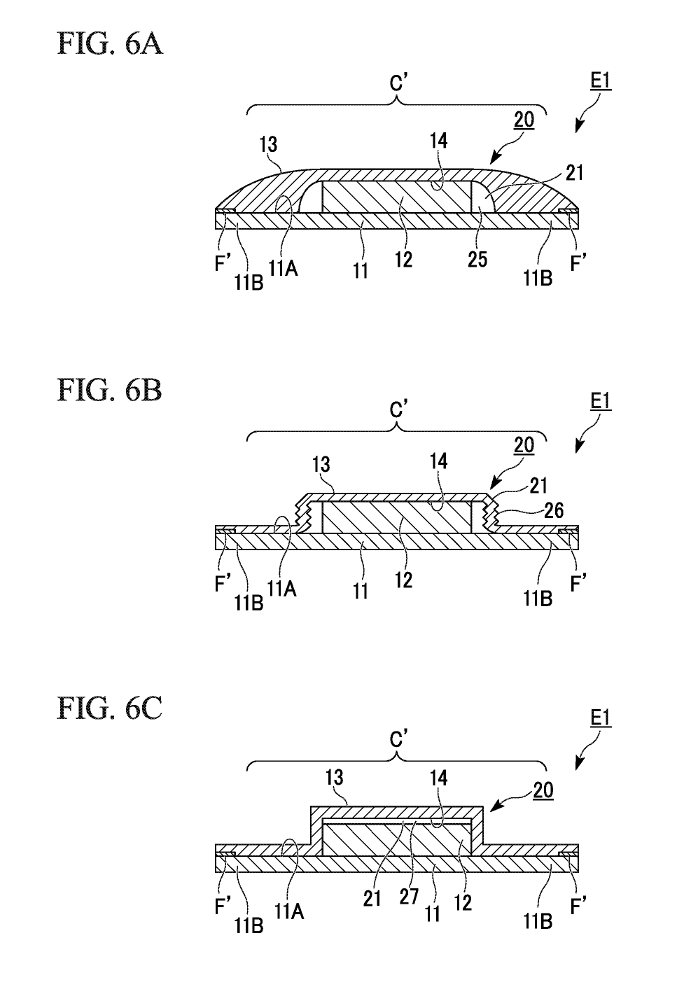

As shown in FIG. 6A, the bent section 21 formed in the deformation section 20 may be constituted by a space section 25 disposed inside the coating layer 13 and formed at a side portion of the circuit receiving section 14 having a concave shape. Distortion absorption performance of the deformation section 20 can be further improved by deformation of the bent section 21.

### (Variant 6)

As shown in FIG. 6B, in the bent section 21 formed in the deformation section 20, a portion of the coating layer 13 disposed at a side portion of the circuit receiving section 14 having a concave shape may be formed in a bellows shape 26. Distortion absorption performance of the deformation section 20 can be further improved by deformation of the bent section 21.

### (Variant 7)

As shown in FIG. 6C, the bent section 21 formed in the deformation section 20 forms a gap 27 between the inner surface of the circuit receiving section 14 having a concave shape and the electronic component 12 accommodated in the circuit receiving section 14, and distortion absorption performance of the deformation section 20 may be further improved by shape deformation of the gap 27.

### (Variant 8)

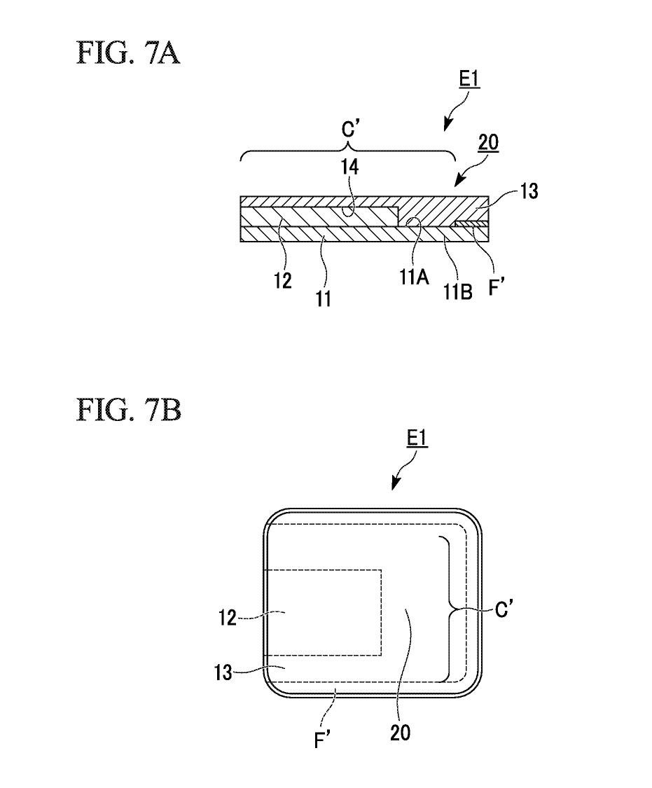

In addition, in the second embodiment, as shown in FIGS. 3A and 3B, the fixed region F′ configured to fix the coating layer 13 to the flexible display unit 11 is formed over the entire circumference of the coating layer 13 along the end portion 11B of the flexible display unit 11. However, there is no limitation thereto, and as shown in FIGS. 7A and 7B, the fixed region F′ configured to fix the coating layer 13 to the flexible display unit 11 may be formed in a portion (in the example, three edge portions) of the coating layer 13 along the end portion 11B of the flexible display unit 11.

### Third Embodiment

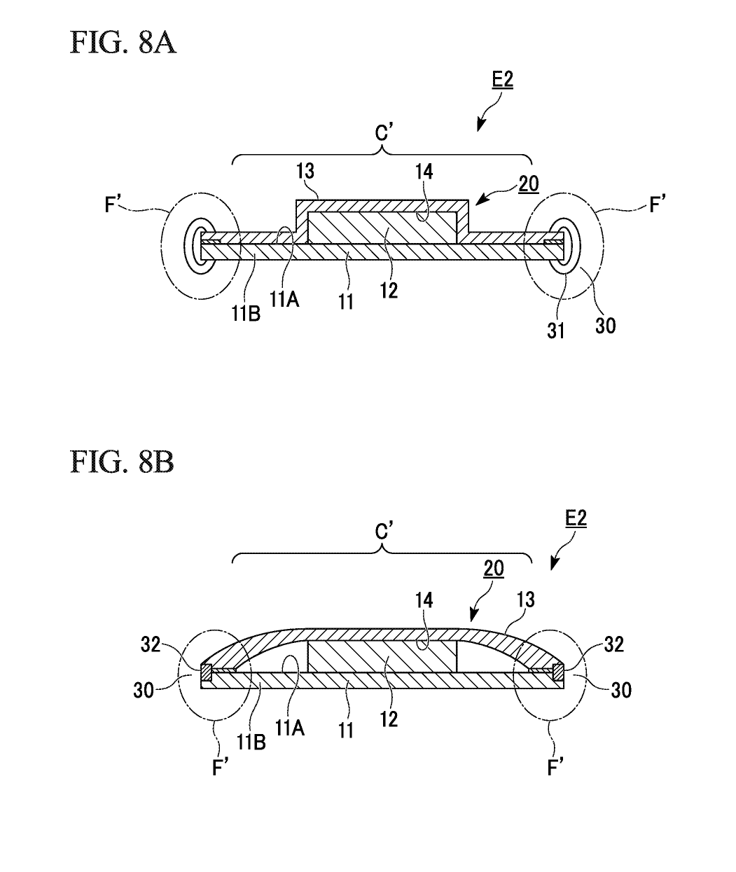

A display device E2 according to a third embodiment of the present invention will be described with reference to FIGS. 8A and 8B.

The display device E2 shown in the third embodiment is distinguished from the display device El of the second embodiment in that a fixing means 30 configured to fix a circumferential edge portion of the coating layer 13 is formed in the fixed region F′ of the end portion 11B of the flexible display unit 11.

Specifically, as shown in FIG. 8A, the fixing means 30 may be formed as a cap member 31 configured to fix the circumferential edge portion of the coating layer 13.

Further, as shown in FIG. 8B, the fixing means 30 may be formed as a fastening member 32 such as a latch or a screw configured to fix the circumferential edge portion of the coating layer 13.

The cap member 31 and the fastening member 32 as the fixing means 30 shown in the third embodiment may be used individually or in combination. Further, the fixed region F′ configured to fix the coating layer 13 to the flexible display unit 11 shown in the first embodiment through adhesion may be used in combination.

In the display device E2 shown in the third embodiment, as the deformation section 20 is formed inside the fixed region F′ configured to fix the coating layer 13 and in the coating region C′ different from the fixed region F′, distortion upon bending of the flexible display unit 11 is absorbed. At the same time, in the display device E2, when a bending operation is performed on the display device E2, the circumferential edge portion of the coating layer 13 is prevented from being delaminated from the end portion 11B of the flexible display unit 11 by the fixing means 30.

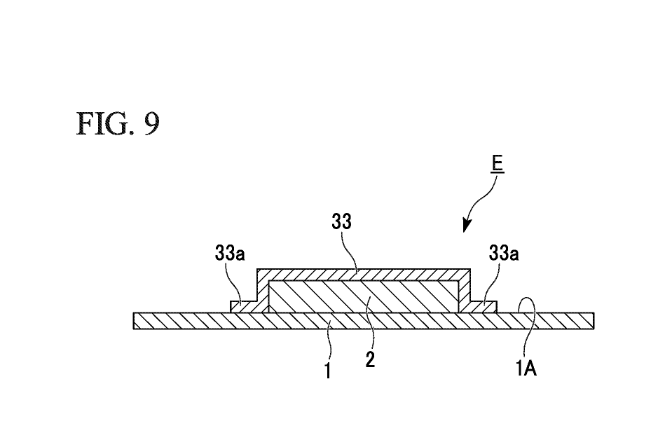

FIG. 9 shows a fourth embodiment of the present invention.

In the first to third embodiments, the case in which the coating layer 3 covers the flexible display unit 1 as a whole and the coating layer 3 is longer than at least the flexible display unit 1 in the shown cross section has been described. However, the coating layer 3 may not be longer than the flexible display unit 1 in the cross section. In the fourth embodiment, the coating layer 33 is formed to cover only the electronic component 2.

The coating layer 33 is formed to cover the electronic component 2 installed on one surface of the flexible display unit 1. That is, the coating layer 33 is formed to have a length such that both end portions 33a are disposed at side portions of the electronic component 2. In this way, even when only a portion of the flexible display unit 1 is covered with the coating layer 33, the flexible display unit 1 can be reinforced as a whole to be protected from excessive bending.

Further, in the above-mentioned embodiment, while the case in which the electronic component 2 has stiffness higher than that of the flexible display unit has been described, the present invention can also be applied to the case in which the electronic component has the same structure as the flexible display unit or a more flexible structure. In addition, in the embodiment, while the electronic component 2 is installed in a region except for both ends in a cross section (not shown) of the flexible display unit 1 (i.e., an outer circumferential edge of the flexible display unit 1), the electronic component 2 may be formed at a region including the end portions. In addition, in the example, while the electronic component 2 is covered with the coating layer 3 as a whole, a portion of the electronic component 2 may be covered with the coating layer 3.

Further, while the embodiments and/or variants thereof have been variously described, these examples may be used individually or may be selectively combined.

Hereinabove, while the embodiment of the present invention has been described in detail with reference to the accompanying drawings, the specific configuration is not limited to the embodiments and design changes or the like may be made without departing from the spirit of the present invention.

Priority is claimed on Japanese Patent Application No. 2014-191827, filed Sep. 19, 2014, the content of which is incorporated herein by reference.

### INDUSTRIAL APPLICABILITY

The present invention can be applied to a display device having a flexible display unit, and can effectively protect the flexible display unit while maintaining flexibility of the flexible display unit.

### REFERENCE SYMBOLS LIST

1 Flexible display unit
1A One surface
1B End portion
2 Electronic component
3 Coating layer
10 Deformation section
11 Flexible display unit
11A One surface
11B End portion
12 Electronic component
13 Coating layer
14 Circuit receiving section
20 Deformation section
21 Bent section
24 Elastic material
25 Space
26 Bellows
27 Gap
33 Coating layer
E Display device
E1 Display device
F Fixed region
F′ Fixed region
C Coating region
C′ Coating region

1. A display device comprising:
a flexible display unit;
an electronic component installed on one surface of the flexible display unit; and
a film layer disposed at one surface of the flexible display unit to cover the electronic component,
wherein the film layer is fixed to an end portion of the flexible display unit.

2. The display device according to claim 1, wherein the electronic component is formed of a material having stiffness higher than that of the flexible display unit.

3. The display device according to claim 1, wherein the coating layer has a fixed region fixed to at least one of at least a portion of the one surface of the flexible display unit and the end portion of the flexible display unit, a coating region configured to cover the electronic component is disposed inside the fixed region, and a deformation section configured to absorb distortion upon bending of the flexible display unit is formed.

4. The display device according to claim 1, wherein the electronic component is disposed other than on the end portion of the flexible display unit, and the coating layer is fixed to the end portion of the display unit.

5. The display device according to claim 1, wherein the coating layer is an elastically deformable material.

6. The display device according to claim 1, wherein the coating layer is fixed to both end portions of the flexible display unit at fixing places, and fixed to the flexible display unit or the electronic component between the fixing places.

7. The display device according to claim 3, wherein the fixed region of the coating layer is formed along the end portion of the flexible display unit.

8. The display device according to claim 1, wherein the coating layer has a length in a direction along a surface of the coating layer larger than that of the flexible display unit, and
a circumferential edge portion of the coating layer is fixed to the end portion of the flexible display unit.

9. The display device according to claim 1, wherein the coating layer has a length in a direction along the surface of the coating layer smaller than that of the flexible display unit, and
the circumferential edge portion of the coating layer is fixed to the one surface of the flexible display unit.

10. The display device according to claim 3, wherein the deformation section of the coating layer is deformable in a state in which the coating region is movable relative to the electronic component.

11. The display device according to claim 3, wherein the deformation section of the coating layer has a bent section formed at the surroundings to cover the electronic component and configured to absorb distortion upon bending of the flexible display unit.

12. The display device according to claim 11, wherein the bent section has a region in which a thickness of the coating layer varies.

13. The display device according to claim 11, wherein the bent section has a space section formed in the coating layer.

14. The display device according to claim 11, wherein the bent section has a region serving as a portion of the coating layer and formed of an elastic material more flexible than the other portion.

15. The display device according to claim 11, wherein the bent section has a bellows formed on the coating layer.

16. The display device according to claim 1, wherein a circuit receiving section formed in a concave shape and having a cross section discontinuously bent to dispose the electronic component is formed on an inner surface of the coating layer.

17. The display device according to claim 16, wherein the coating layer in which the circuit receiving section is formed has a thickness smaller than that of the other portion.

18. The display device according to claim 16, wherein the electronic component is closely disposed in a concave section of the circuit receiving section.

19. The display device according to claim 16, wherein the electronic component is disposed in the concave section of the circuit receiving section with a gap.

20. (canceled)

21. A method of manufacturing a display device, the method comprising:
a process of stacking an electronic component on one surface of a flexible display unit; and
a process of stacking a coating layer, a portion or the entirety of which is deformable according to deformation of the flexible display unit, on one surface of the flexible display unit to cover the electronic component.
